(19) United States
(12) Patent Application Publication
(10) Pub. No.: US 2026/0123483 A1
(43) Pub. Date: Apr. 30, 2026

(54) SUBSTRATE, SEMICONDUCTOR PACKAGE INCLUDING THE SUBSTRATE AND MANUFACTURING METHOD FOR THE SUBSTRATE

(71) Applicant: Samsung Electronics Co., Ltd., Suwon-si (KR)

(72) Inventors: Wongu LEE, Suwon-si (KR); Yongjae KIM, Suwon-si (KR); Hyeonjae KIM, Suwon-si (KR); Jihong PARK, Suwon-si (KR); Seung-Kwan RYU, Suwon-si (KR)

(73) Assignee: Samsung Electronics Co., Ltd., Suwon-si (KR)

(21) Appl. No.: 19/198,571

(22) Filed: May 5, 2025

(30) Foreign Application Priority Data
Oct. 31, 2024 (KR) 10-2024-0152694

(51) Int. Cl. H01L 23/498; H01L 21/48; H01L 23/538; H01L 25/065; H01L 25/18

(52) U.S. Cl. CPC H10W 70/65; H10W 70/095; H10W 70/611; H10W 70/635; H10W 70/69; H10W 90/00

(57) ABSTRACT

The present disclosure as at least one example embodiment provides a substrate including a base substrate having a first penetration portion penetrating between a front surface and a back surface; a wiring structure on the front surface of the base substrate; a insulation layer on the back surface of the base substrate and having a second penetration portion extending from the first penetration portion; a penetration via filling a portion of the second penetration portion and the first penetration portion and connected to the wiring structure; and a conductive pad filling a remaining part of the second penetration portion and connected to the penetration via, wherein the penetration via is recessed by 700 nanometers (nm) to 1100 nm from the first surface of the insulation layer.

### CROSS-REFERENCE TO RELATED APPLICATION

This application claims priority to and the benefit of Korean Patent Application No. 10-2024-0152694 filed in the Korean Intellectual Property Office on Oct. 31, 2024, the entire contents of which are incorporated herein by reference.

### BACKGROUND OF THE INVENTION

### (a) Field of the Invention

The present disclosure relates to a substrate, a semiconductor package including the substrate, and a substrate manufacturing method.

### (b) Description of the Related Art

In a semiconductor package industry, a two and a half dimensional (2.5D) package structure is known in which a plurality of semiconductor chips is placed on an interposer substrate (e.g., silicon interposer substrate) and then mounted on a printed circuit board (PCB). An interposer substrate connects semiconductor chips to each other and acts as an intermediate substrate between the semiconductor chips and a printed circuit board (PCB), enabling high-speed signal transmission and high integration between semiconductor chips.

### SUMMARY OF THE INVENTION

The present disclosure, in one aspect, seeks to provide a substrate, a semiconductor package including the substrate, and a substrate manufacturing method capable of improving an alignment between a penetration via and a conductive pad by securing a visibility of the penetration via in an exposure process for forming a conductive pad.

The present disclosure as at least one example embodiment provides a substrate including a base substrate having a front surface, a back surface opposite to the front surface, and a first penetration portion penetrating between the front surface and the back surface; a wiring structure on the front surface of the base substrate; an insulation layer including one or more layers on the back surface of the base substrate and having a second penetration portion extending from the first penetration portion; a penetration via filling a portion of the second penetration portion and filling the first penetration portion such that the penetration via is connected to the wiring structure; and a conductive pad extending onto a first surface of the insulation layer and filling a remaining part of the second penetration portion such that the conductive pad is connected to the penetration via, wherein a surface of the penetration via facing the conductive pad is recessed by 700 nanometers (nm) to 1100 nm from the first surface of the insulation layer.

The present disclosure as at least one embodiment provides a semiconductor package including a substrate; and a plurality of semiconductor chips disposed side by side on the substrate; wherein the substrate includes a base substrate having a front surface, a back surface opposite to the front surface, and a first penetration portion penetrating between the front surface and the back surface; a wiring structure on the front surface of the base substrate; an insulation layer on the back surface of the base substrate and having a second penetration portion extending from the first penetration portion; a penetration via filing a portion of the second penetration portion and filling the first penetration portion such that the penetration via is connected to the wiring structure; and a conductive pad extending onto a first surface of the insulation layer and filling a remaining part of the second penetration portion such that the conductive pad is connected to the penetration via, and a surface of the penetration via facing the conductive pad is recessed by 700 nm to 1100 nm from the first surface of the insulation layer.

The present disclosure as at least one embodiment provides a substrate manufacturing method includes forming a penetration via in a base substrate such that the penetration via is extended in a direction from a front surface of the base substrate toward a first back surface of the base substrate and such that the penetration via is embedded in the base substrate; removing the first back surface of the base substrate such that a second back surface is formed and such that the penetration via protrudes from the second back surface of the base substrate; forming an insulation layer on the second back surface of the base substrate and on a region of the penetration via protruding from the second back surface of the base substrate; exposing the penetration via by removing a portion of the insulation layer and a portion of the penetration via; removing a second portion of the penetration via such that the penetration via is recessed by 700 nanometers (nm) to 1100 nm from a first surface of the insulation layer; and forming a conductive pad on the penetration via such that the conductive pad extends onto the first surface of the insulation layer.

According to one aspect of the present disclosure, the substrate capable of improving the alignment between the penetration via and the conductive pad by securing a visibility of the penetration via in an exposure process for forming the conductive pad, the semiconductor package including the substrate, and the substrate manufacturing method may be provided.

### BRIEF DESCRIPTION OF THE DRAWINGS

FIG. 1 is a cross-sectional view of a substrate according to at least one example embodiment.

FIG. 2 is an enlarged view of a region of FIG. 1.

FIG. 3 is a cross-sectional view of a semiconductor package according to at least one example embodiment.

FIG. 4 to FIG. 15 are manufacturing process diagrams of a substrate according to at least one example embodiment.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In order to elucidate the present invention, parts that are not related to the description will be omitted. Like reference numerals designate like elements throughout the specification.

In addition, the size and thickness of each component shown in the drawings are arbitrarily shown for ease of understanding and description, but the present invention is not limited thereto. In the drawings, the thickness of layers, films, panels, regions, etc., are exaggerated for clarity. In addition, in the drawings, for understanding and ease of description, the thicknesses of some layers and areas are exaggerated. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Throughout this specification and the claims that follow, when it is described that an element is “coupled” to another element, this includes not only cases where it is “directly connected” but also cases where it is “indirectly connected” through another member. From a similar perspective, this includes not only being “physically connected” but also being “electrically connected”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “in a plan view” means when an object portion is viewed from the above, and the phrase “in a cross-section” means when a cross-section taken by vertically cutting an object portion is viewed from the side.

Additionally, throughout the specification, the sequential numbers, such as a first, a second, etc., are used to distinguish a component from other identical or similar components, and are not necessarily intended to refer to a specific component. Thus, a component referred to as a first component in a particular part of this specification may be referred to as a second component in another part of this specification.

Additionally, throughout the specification, a singular reference to any component includes a plurality of references to that component, unless otherwise stated.

Additionally, throughout the specification, references to one surface and the other surface are intended to distinguish between different sides and are not necessarily intended to be limited to a particular surface. Accordingly, a surface referred to as one surface in a particular part of this specification may be referred to as the other surface in another part of this specification.

Additionally, throughout the specification, references to directions such as an upper surface, an upper side, an upper part, a lower surface, a lower side, a lower part, etc. are provided with reference to the drawings to aid explanation and understanding. For example, such spatially relative terms are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

Hereinafter, a substrate, a semiconductor package including the substrate, and a substrate manufacturing method of the present disclosure are described with reference to the drawing.

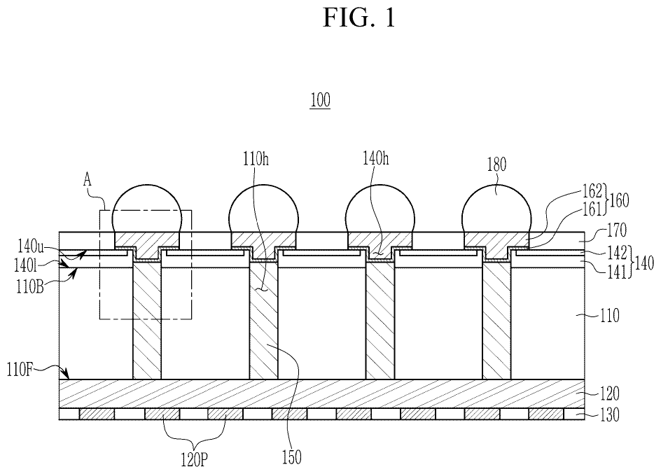

FIG. 1 is a cross-sectional view of a substrate according to at least one example embodiment.

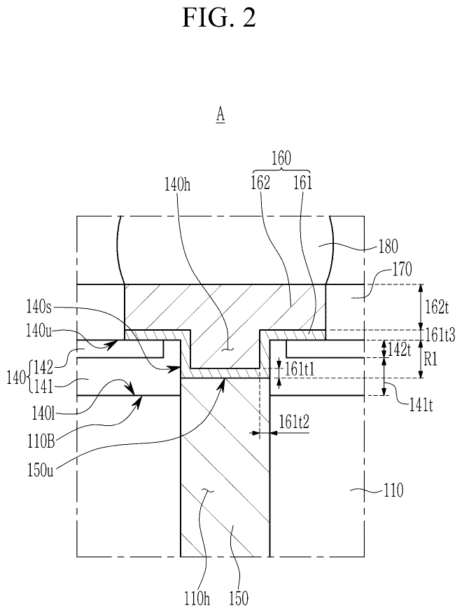

FIG. 2 is an enlarged view of a region A of FIG. 1.

A substrate 100 may include a base substrate 110, a wiring structure 120, a first protective layer 130, an insulation layer 140, a penetration via 150, a conductive pad 160, and a second protective layer 170. In at least some embodiments, the substrate 100 may include a conductive bump 180 on the conductive pad 160.

The substrate 100 may be an interposer substrate. The interposer substrate may connect semiconductor chips to each other and act as an intermediate substrate between the semiconductor chips and a printed circuit board (PCB).

The base substrate 110 may have a front surface 110F and a back surface 110B, which are opposite sides, and a first penetration portion 110h.

The first penetration portion 110h may penetrate the base substrate 110 and extend between the front surface 110F and the back surface 110B in a direction from the front surface 110F toward the back surface 110B. The first penetration portion 110h may be formed by processing (e.g., etching, removing a portion of, etc.) the base substrate 110 in the direction from the front surface 110F of the base substrate 110 toward the back surface 110B. The first penetration portion 110h may be filled with a conductive material to form the penetration via 150.

In at least one example embodiment, the base substrate 110 may be formed of an insulating material. For example, the base substrate 110 may be formed of other insulating materials such as glass or organic materials. Additionally, in at least one example embodiment, the base substrate 110 may include a semiconductor element such as silicon (Si) or a compound semiconductor such as gallium arsenide (GaAs) or indium arsenide (InAs). That is, the substrate 100 may be an interposer substrate utilizing a semiconductor such as silicon. The thickness of the base substrate 110 may be tens to hundreds of microns (μm), for example about 100 μm.

The wiring structure 120 may be on the front surface 110F of the base substrate 110. The wiring structure 120 may be electrically connected to the penetration via 150 and may include a conductive pad 120P configured to form an electrical connection with other components (e.g., semiconductor chips) mounted on the substrate 100. Additionally, the wiring structure 120 may include further wiring layers positioned between the penetration via 150 and the conductive pad 120P. The wiring layers may be embedded in the insulation layer and electrically connected by vias.

The first protective layer 130 may be arranged on the wiring structure 120 to cover at least a portion of the conductive pad 120P and expose the lower surface of the conductive pad 120P. For example, the first protective layer 130 may cover the surface of the conductive pad 120P. The first protective layer 130 may further cover the edge region of the lower surface of the conductive pad 120P and have an opening that exposes the center region of the lower surface of the conductive pad 120P. The first protective layer 130 may be formed of an insulating material such as a solder resist.

The insulation layer 140 may be disposed on the back surface 110B of the base substrate 110 and may have a second penetration portion 140h extending from the first penetration portion 110h.

The second penetration portion 140h may penetrate between the upper surface 140u and the lower surface 140l in a direction from the upper surface 140u of the insulation layer 140 toward the lower surface 140l. The second penetration portion 140h may overlap the first penetration portion 110h. For example, the shape and diameter of the second penetration portion 140h may be the same as those of the first penetration portion 110h. The second penetration portion 140h may be formed by forming the penetration via 150 to extend to the formation region of the second penetration portion 140h and covering the base substrate 110 and the penetration via 150 with an insulation layer 140. That is, the second penetration portion 140h may correspond to a region of the back surface 110B of the base substrate 110 where the insulation layer 140 is not covered by the penetration via 150.

In at least one example embodiment, the insulation layer 140 may be composed of a plurality of insulation layers 140. For example, insulation layer 140 may include a first insulation layer 141 and a second insulation layer 142 disposed on the first insulation layer 141.

The first insulation layer 141 may extend between the region filling the second penetration portion 140h of the conductive pad 160 and the second insulation layer 142. In these cases, this is because the first insulation layer 141 and the second insulation layer 142 may be sequentially formed on the surface of the penetration via 150 and some of the first insulation layer 141 and the second insulation layer 142 may be removed together with the penetration via 150.

The first insulation layer 141 may provide an electrical insulation, a contamination protection, and a surface protection for the base substrate 110, and may planarize the surface on which the second insulation layer 142 is deposited to strengthen the adhesion between the base substrate 110 and the second insulation layer 142. In at least one example embodiment, the first insulation layer 141 may include silicon oxide. The thickness 141t of the first insulation layer 141 may be about 1620 nanometers (nm) to about 1980 nm.

The second insulation layer 142, together with the first insulation layer 141, may provide an electrical insulation, a contamination protection, and a surface protection to the base substrate 110, and may perform a function of a diffusion barrier that reduces and/or prevents a diffusion of a metal material (e.g., copper (Cu)) into the base substrate 110. In at least one example embodiment, the second insulation layer 142 may include silicon nitride. The thickness 142t of the second insulation layer 142 may be 270 nm to 430 nm. As described below, the penetration via 150 is recessed from the upper surface 140u of the insulation layer 140 by a certain depth, and the depth R1 of the penetration via 150 recessed from the upper surface 140u of the insulation layer 140 may be greater than the thickness of the second insulation layer 142. Therefore, the upper surface 150u of the penetration via 150 may be positioned at a lower level than the lower surface of the second insulation layer 142.

The penetration via 150 may fill the first penetration portion 110h to be connected to the wiring structure 120, and may further fill the part of the second penetration portion 140h. That is, the penetration via 150 may penetrate the base substrate 110 and extend into the insulation layer 140.

In the present disclosure, the upper surface 150u facing the conductive pad 160 of the penetration via 150 has a step difference from the upper surface 140u of the insulation layer 140. For example, the upper surface 150u of the penetration via 150 may be recessed to a certain depth from the upper surface 140u of the insulation layer 140. Accordingly, the first metal layer 161 formed on the penetration via 150 and the first metal layer 161 formed on the insulation layer 140 may also have the step, and the visibility of the penetration via 150 may be secured even after the first metal layer 161 is formed.

The upper surface 150u of the penetration via 150 may be recessed by 700 nm to 1100 nm from the upper surface 140u of the insulation layer 140. That is, the depth R1 of the penetration via 150 recessed from the upper surface 140u of the insulation layer 140 may be 700 nm to 1100 nm. For example, the upper surface 150u of the penetration via 150 may be recessed about 900 nm from the upper surface 140u of the insulation layer 140. If the depth R1 of the penetration via 150 recessed from the upper surface 140u of the insulation layer 140 is less than 700 nm, it is difficult to secure the visibility of the penetration via 150, and if it exceeds 1100 nm, a production cost and a time may unnecessarily increase.

The conductive pad 160 may be connected to the penetration via 150 by filling the remaining part of the second penetration portion 140h and extend onto the upper surface 140u of the insulation layer 140. For example, the conductive pad 160 may be placed on the upper surface 140u of the insulation layer 140 and extend into the insulation layer 140 to be in contact with the penetration via 150.

The conductive pad 160 may extend over the upper surface 140u of the insulation layer 140 to provide a stable connection. Therefore, the cross-sectional width on the upper surface 140u of the insulation layer 140 of the conductive pad 160 may be slightly larger than the cross-sectional width in the region filling the second penetration portion 140h.

The conductive pad 160 may include a first metal layer 161 and a second metal layer 162.

The first metal layer 161 may be a seed layer for forming the second metal layer 162. The first metal layer 161 may be extended onto the upper surface 140u of the insulation layer 140, the wall surface 140s of the second penetration portion 140h, and the upper surface 150u of the penetration via 150. The first metal layer 161 may be formed by a physical vapor deposition (PVD) etc., such as sputtering, a chemical vapor deposition (CVD), an atomic layer deposition (ALD), etc.

The first metal layer 161 may be deposited on the upper surface 140u of the insulation layer 140, the wall surface 140s of the second penetration portion 140h, and the upper surface 150u of the penetration via 150 with the same or similar thickness. For example, the thickness 161t3 of the first metal layer 161 on the upper surface 140u of the insulation layer 140 and the thickness 161t1 thereof on the upper surface 150u of the penetration via 150 may be the same or substantially similar. However, when the forming material of the deposition direction of the first metal layer 161 is considered, the thickness 161t2 of the first metal layer 161 on the wall surface 140s of the second penetration portion 140h may be slightly thinner than the thickness 161t3 on the upper surface 140u of the insulation layer 140 and the thickness 161t1 on the upper surface 150u of the penetration via 150.

As the first metal layer 161 is deposited with the same or similar thickness, the region of the first metal layer 161 disposed on the upper surface 140u of the insulation layer 140 and the region disposed on the upper surface 150u of the penetration via 150 may have a step. That is, the upper surface of the region of the first metal layer 161 arranged on the upper surface 140u of the insulation layer 140 may be positioned at a higher level with respect to the base substrate 110 than the upper surface of the region arranged on the upper surface 150u of the penetration via 150. For example, the thickness 161t3 of the first metal layer 161 on the upper surface 140u of the insulation layer 140 and the thickness 161t1 thereof on the upper surface 150u of the penetration via 150 may be 200 nm to 300 nm, for example about 250 nm. If the thicknesses 161t1 and 161t3 of the first metal layer 161 is less than 200 nm, the first metal layer 161 is physically and mechanically unstable, and it may be difficult for the current to be uniformly distributed on the surface of the first metal layer 161 during the plating process for forming the second metal layer 162. If the thicknesses 161t1 and 161t3 of the first metal layer 161 exceeds 300 nm, an electrical resistance may increase, and a production cost and a time may increase. As described above, the thickness 161t2 of the first metal layer 161 on the wall surface 140s of the second penetration portion 140h may be slightly thinner than the thickness 161t3 thereof on the upper surface 140u of the insulation layer 140 and the thickness 161t1 thereof on the upper surface 150u of the penetration via 150.

The second metal layer 162 may be placed on the first metal layer 161. The second metal layer 162 may be formed through a plating process, for example an electroplating. In the electroplating, the first metal layer 161 may act as a seed layer to aid the growth of the second metal layer 162. The thickness 162t of the second metal layer 162 may be thicker than the thicknesses 161t1, 161t2, and 161t3 of the first metal layer 161. For example, the second metal layer 162 may have the thickness from several microns to tens or hundreds of microns (μm).

Each material of the first metal layer 161 and the second metal layer 162 may use a conductive material, and for example, metals such as copper (Cu), aluminum (Al), nickel (Ni), gold (Au), silver (Ag), palladium (Pd), titanium (Ti), or alloys thereof, and/or the like may be used.

At least one additional metal layer (e.g., a nickel (Ni) layer and a gold (Au) layer) may be disposed on the second metal layer 162 for the purpose of protecting the surface of the second metal layer 162 and strengthening the adhesion to the conductive bump 180.

The second protective layer 170 may be disposed on the insulation layer 140 to cover at least a portion of the conductive pad 160 and expose the upper surface of the conductive pad 160. For example, the second protective layer 170 may cover the side of the conductive pad 160. The second protective layer 170 may further cover the edge region of the upper surface of the conductive pad 160 and have an opening that exposes the center region of the upper surface of the conductive pad 160. The second protective layer 170 may be formed of an insulating material such as a solder resist.

The conductive bump 180 may be placed on the conductive pad 160. The conductive bump 180 may be connected to the conductive pad 160 so that the substrate 100 may be electrically connected to an external component. The conductive bump 180 can be formed with a conductive amalgam or material such as solder.

Meanwhile, when forming the interposer substrate, a pad (also referred to as a redistribution layer) connected to a penetration via may be formed on the back surface of a base substrate (e.g., silicon substrate) through a photolithography process. In the photolithography process, the position of the penetration via is recognized to set an exposure region of a photoresist layer. At this time, it is difficult to secure the visibility of the penetration via due to the seed layer continuously deposited on the base substrate and the penetration via, making it difficult to set an accurate exposure region, and there may be a problem of inaccurate alignment between the penetration via and the conductive pad.

According to the present disclosure, by forming the step in the penetration via and the insulation layer, the seed layer deposited on the penetration via and the seed layer deposited on the insulation layer have the step, the visibility of the penetration via may be secured even after the seed layer is formed. Therefore, the accurate exposure region may be set based on the position of the penetration via recognized after the seed layer is formed, and the alignment of the penetration via and the conductive pad can be improved.

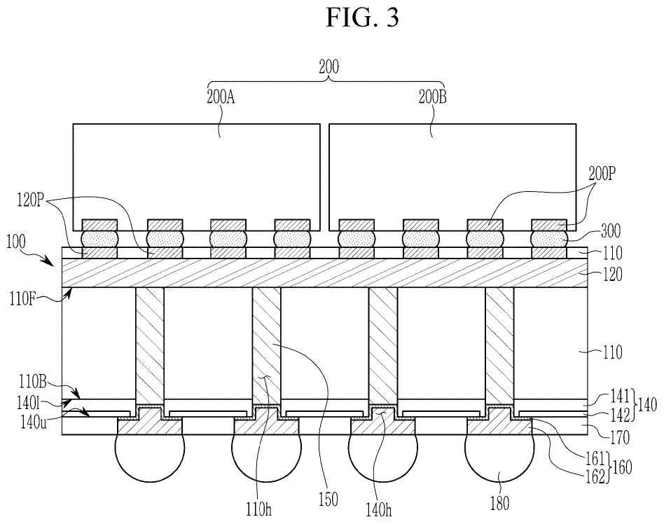

FIG. 3 is a cross-sectional view of a semiconductor package according to at least one example embodiment.

A semiconductor package according to at least one example embodiment may include the substrate 100 and a plurality of semiconductor chips 200 arranged side by side on the substrate 100.

As noted above, the substrate 100 may be an interposer substrate and may electrically connect the semiconductor chips 200. The substrate 100 may also perform other roles, such as controlling the wiring pitch.

The semiconductor chip 200 may have a connection pad 200P for connection to an external component. The material of the connection pad 200P may be a conductive material, and for example, metals such as copper (Cu), aluminum (Al), nickel (Ni), gold (Au), silver (Ag), palladium (Pd), titanium (Ti), and/or alloys thereof may be used.

The semiconductor chips 200 may include a first semiconductor chip 200A and a second semiconductor chip 200B. The number of the semiconductor chips 200 may be greater than that shown in the drawing, and according to at least one example embodiment, only a single semiconductor chip 200 may be placed on the substrate 100.

The type of each semiconductor chip 200 is not particularly limited, and may be various types of chips such as, for example, logic chips, memory chips, and system on chips (SOC). The logic chip at least one of an application processor (AP), a microprocessor, a central processing unit (CPU), a graphic processing unit (GPU), a neural processing unit (NPU), an application specific integrated circuit (ASIC), and a system on chip (SoC). The memory chip may include at least one of a high bandwidth memory (HBM) chip, a dynamic random access memory (DRAM) chip, a static random access memory (SRAM) chip, a flash memory chip, a read-only memory (ROM) chip, and a magnetic random access memory (MRAM) chip.

A conductive bump 300 may be placed between each semiconductor chip 200 and the substrate 100. The conductive bump 300 may secure the semiconductor chip 200 on the substrate 100 and provide an electrical connection between the semiconductor chip 200 and the substrate 100. The conductive bump 300 may be formed of a conductive material such as a solder.

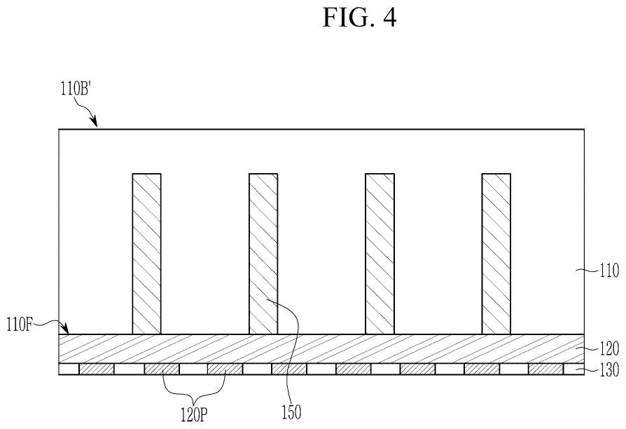

FIG. 4 to FIG. 15 are manufacturing process diagrams of a substrate according to at least one example embodiment.

First, referring to FIG. 4, a penetration via 150 is formed by extending in a direction from a front surface 110F of a base substrate 110 toward a first back surface 110B′ and embedded in the base substrate 110. One end of the penetration via 150 may be covered by the base substrate 110 and the other end may be connected to the wiring structure 120 and/or the conductive pad 160. The penetration via 150 may be formed by a via first, via middle or via last method.

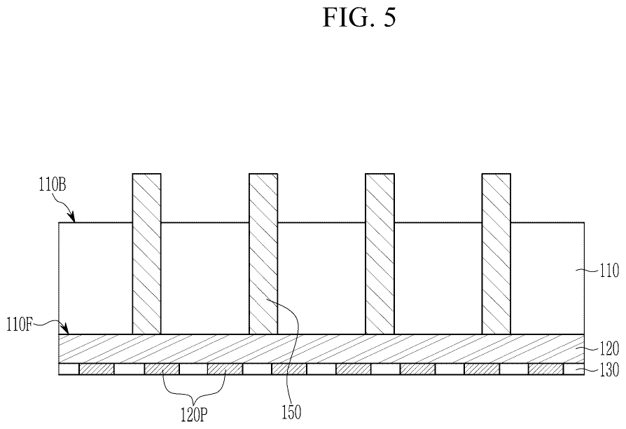

Next, referring to FIG. 5, the first back surface 110B′ of the base substrate 110 is removed to form a second back surface 110B, and the penetration via 150 is protruded onto the second back surface 110B of the base substrate 110. The first back surface 110B′ of the base substrate 110 may be removed by, for example, etching.

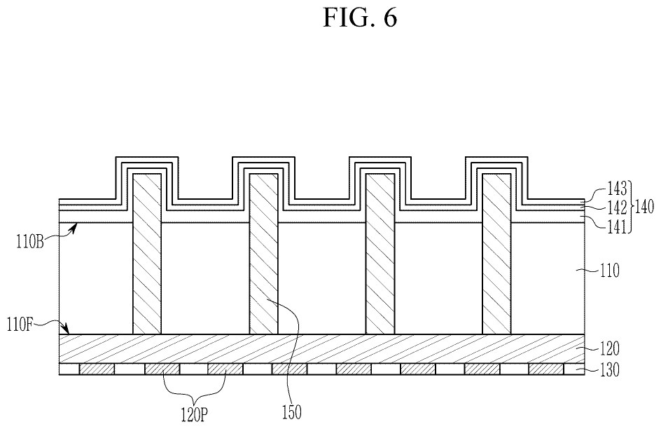

Next, referring to FIG. 6, one or more insulation layers 140 are formed on the second back surface 110B of the base substrate 110 and on the region protruded onto the base substrate 110 of the penetration via 150. The insulation layer 140 may include a first insulation layer 141, a second insulation layer 142, and a third insulation layer 143, which may be sequentially formed on the surface of the base substrate 110 and the penetration via 150. For example, the insulation layer 140 may be formed by forming the first insulation layer 141 depositing silicon oxide of the surfaces of the base substrate 110 and the penetration via 150, forming the second insulation layer 142 by depositing silicon nitride on the first insulation layer 141, and forming the third insulation layer 143 by depositing silicon oxide on the second insulation layer 142.

The first insulation layer 141 may provide the electrical insulation, the contamination protection, and the surface protection to the base substrate 110, and planarize the surface on which the second insulation layer 142 is deposited to strengthen the adhesion between the base substrate 110 and the second insulation layer 142. The thickness 141t of the first insulation layer 141 may be about 1620 nm to about 1980 nm.

The second insulation layer 142, together with the first insulation layer 141, may provide an electrical insulation, a contamination protection, and a surface protection to the base substrate 110, and may perform a function of a diffusion barrier that reduces or prevents a diffusion of a metal material (e.g., copper (Cu)) into the base substrate 110. The thickness 142t of the second insulation layer 142 may be 270 nm to 430 nm.

The third insulation layer 143 may be a configuration introduced to mitigate and/or prevent a bending of the penetration via 150 in the subsequent process. The thickness of the third insulation layer 143 may be designed to a range to protect the penetration via 150.

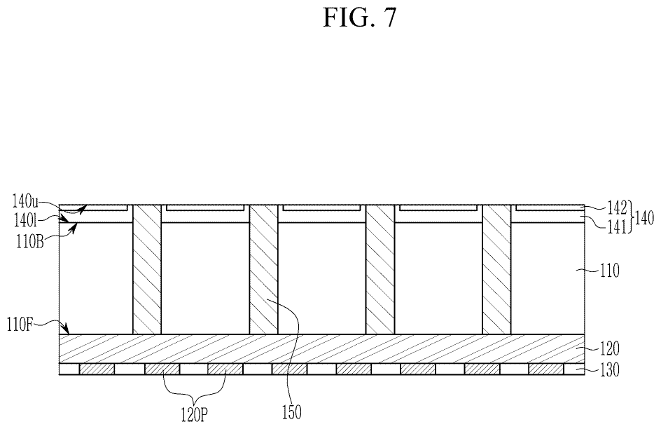

Next, referring to FIG. 7, a part of the insulation layer 140 and the penetration via 150 are removed to expose the penetration via 150. The part of the insulation layer 140 and penetration via 150 may be removed by, for example, a chemical mechanical polishing (CMP). The upper surface of the insulation layer 140 and the upper surface of the penetration via 150 may be planarized by a chemical mechanical polishing. Additionally, the third insulation layer 143 of the insulation layer 140 may be removed entirely, and the third insulation layer 143 may not remain in the manufactured substrate 100.

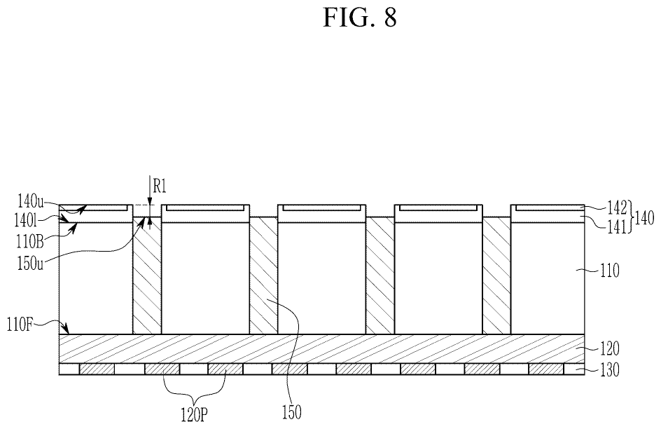

Next, referring to FIG. 8, a portion of the penetration via 150 may be further removed so that the upper surface 150u of the penetration via 150 may be recessed by 700 nm to 1100 nm from the upper surface 140u of insulation layer 140. That is, the depth R1 of the penetration via 150 recessed from the upper surface 140u of the insulation layer 140 may be 700 nm to 1100 nm. Since the upper surface 150u of the penetration via 150 is recessed from the upper surface 140u of the insulation layer 140, the first metal layer 161 formed on the penetration via 150 and the first metal layer 161 formed on the insulation layer 140 may have a step.

In at least one example embodiment, the portion of the penetration via 150 may be removed by a dry etching. When applying the dry etching, a high energy may be used to etch the penetration via 150 to a constant thickness in each region, which may efficiently increase the visibility of the penetration via 150. However, some of the penetration via 150 may be removed by other methods such as a wet etching, a laser processing, a mechanical processing, and/or the like.

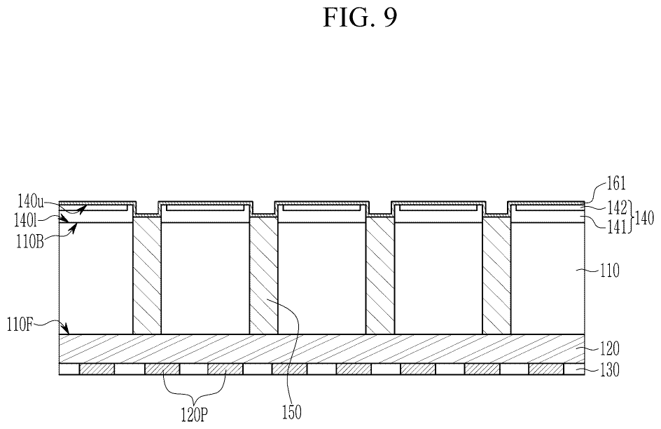

Next, referring to FIG. 9 to FIG. 13, a conductive pad 160 is formed so as to extend onto the upper surface 140u of the insulation layer 140 on the penetration via 150. The conductive pad 160 may include a first metal layer 161 and a second metal layer 162, and be formed using a photoresist layer 10.

First, referring to FIG. 9, the first metal layer 161 is formed so as to extend along the surface of the insulation layer 140 and the surface of the penetration via 150. The first metal layer 161 may be formed by a physical vapor deposition (PVD), a chemical vapor deposition (CVD), an atomic layer deposition (ALD), etc., such as sputtering. As the upper surface 150u of the penetration via 150 is recessed from the upper surface 140u of the insulation layer 140, the first metal layer 161 formed on the penetration via 150 and the first metal layer 161 formed on the insulation layer 140 may also have a step.

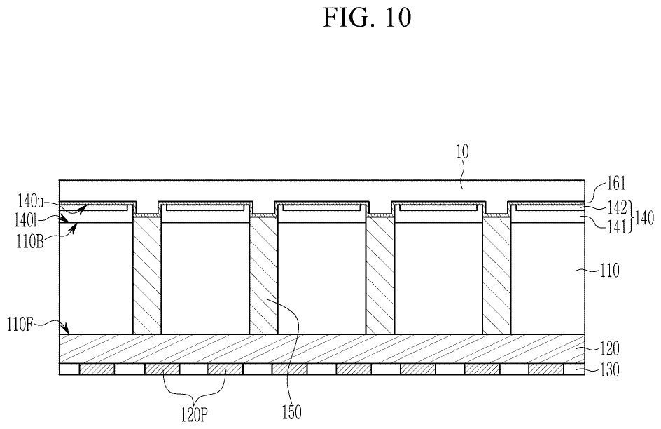

Next, referring to FIG. 10, a photoresist layer 10 is formed on the first metal layer 161. The photoresist layer 10 may be formed by coating a photoresist material on the first metal layer 161 by, for example, a spin coating, a spray coating, a dipping, etc., and curing it.

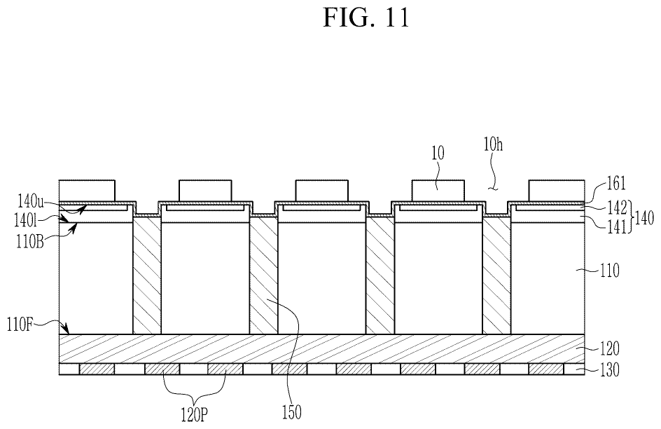

Next, referring to FIG. 11, the photoresist layer 10 is exposed and developed to form an open region 10h. The open region 10h may correspond to the forming region of the second metal layer 162. According to the present disclosure, the position of the penetration via 150 may be recognized by the step formed in the first metal layer 161 during the exposure of the photoresist layer 10, thereby setting a more accurate exposure region.

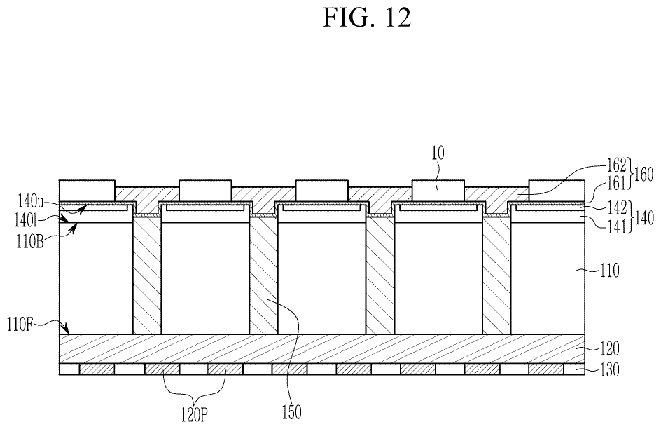

Next, referring to FIG. 12, the second metal layer 162 is filled to the open region 10h of the photoresist layer 10. The second metal layer 162 may be formed through the electrolytic plating. In the electrolytic plating, the first metal layer 161 may act as a seed layer to aid the growth of the second metal layer 162.

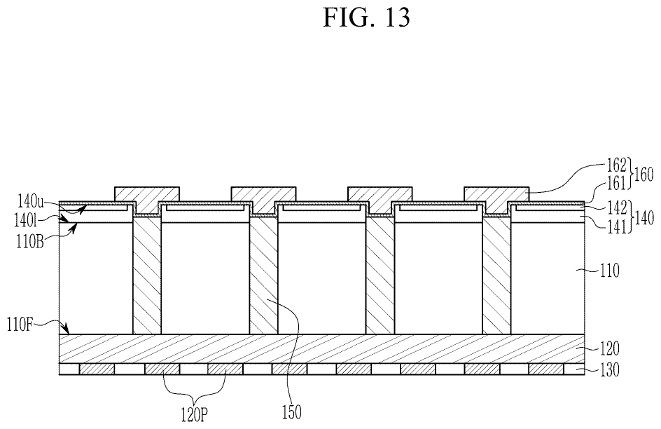

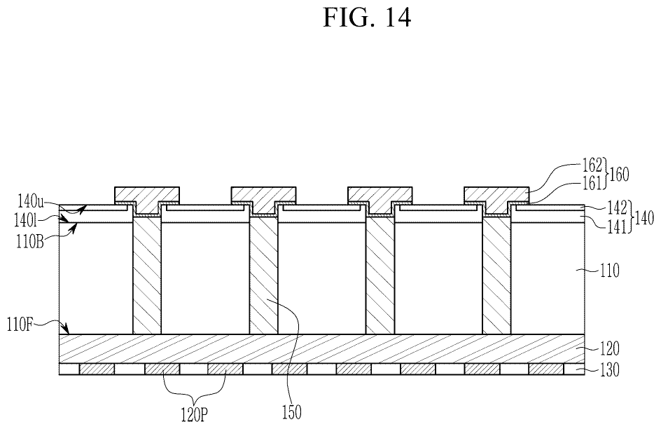

Next, referring to FIG. 13 and FIG. 14, the photoresist layer 10 is removed, and the exposed region of the first metal layer 161 (e.g., the region not covered by the second metal layer 162) is removed. The removal method of the photoresist layer 10 is not specifically limited, and may be removed using a stripper, for example. Additionally, the exposed region of the first metal layer 161 may be removed by, for example, an etching.

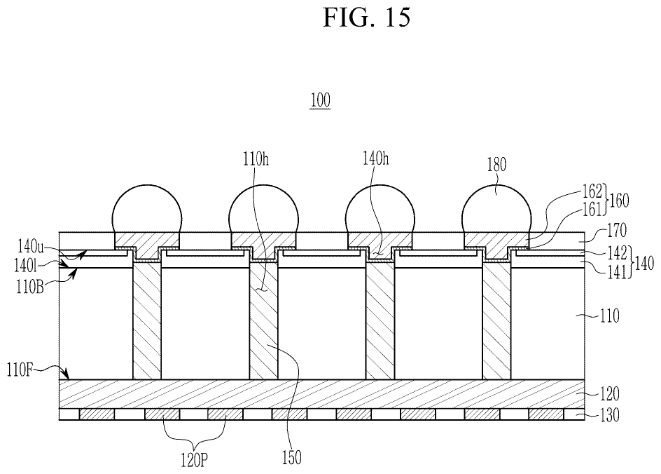

Finally, referring to FIG. 15, a second protective layer 170 may be formed on the insulation layer 140, and a conductive bump 180 may be formed on the conductive pad 160, thereby manufacturing the substrate 100 according to the present disclosure.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

Additionally, the embodiments of the present disclosure are not independent of each other and may be implemented in combination with each other unless specifically contradictory. Therefore, the combined embodiment of the present disclosure should also be considered as included in the present disclosure.

What is claimed is:

1. A substrate comprising:
a base substrate having a front surface, a back surface opposite to the front surface, and a first penetration portion penetrating between the front surface and the back surface;
a wiring structure on the front surface of the base substrate;
an insulation layer including one or more layers on the back surface of the base substrate and having a second penetration portion extending from the first penetration portion;
a penetration via filling a portion of the second penetration portion and filling the first penetration portion such that the penetration via is connected to the wiring structure; and
a conductive pad extending onto a first surface of the insulation layer and filling a remaining part of the second penetration portion such that the conductive pad is connected to the penetration via,
wherein a surface of the penetration via facing the conductive pad is recessed by 700 nanometers (nm) to 1100 nm from the first surface of the insulation layer.

2. The substrate of claim 1, wherein the conductive pad includes
a first metal layer extending onto the first surface of the insulation layer, a wall surface of the second penetration portion, and the recessed surface of the penetration via, and
a second metal layer on the first metal layer.

3. The substrate of claim 2, wherein a region of the first metal layer on the first surface of the insulation layer and a region on the recessed surface of the penetration via form a step.

4. The substrate of claim 2, wherein a thickness of the first metal layer on the first surface of the insulation layer and a thickness on the recessed surface of the penetration via are 200 nm to 300 nm.

5. The substrate of claim 2, wherein a thickness of the first metal layer on the wall surface of the second penetration portion is thinner than a thickness of the first metal layer on the first surface of the insulation layer and on the recessed surface of the penetration via.

6. The substrate of claim 2, wherein a thickness of the second metal layer is thicker than a thickness of the first metal layer.

7. The substrate of claim 1, wherein the insulation layer includes
a first insulation layer, and
a second insulation layer on the first insulation layer.

8. The substrate of claim 7, wherein a depth of the penetration via recessed from the first surface of the insulation layer is greater than a thickness of the second insulation layer.

9. The substrate of claim 7, wherein the first insulation layer extends between a region filling the second penetration portion of the conductive pad and the second insulation layer.

10. The substrate of claim 7, wherein the first insulation layer includes silicon oxide, and the second insulation layer includes silicon nitride.

11. The substrate of claim 7, wherein
a thickness of the first insulation layer is 1620 nm to 1980 nm.

12. The substrate of claim 7, wherein
a thickness of the second insulation layer is 270 nm to 430 nm.

13. The substrate of claim 1, further comprising:
a protective layer on the insulation layer, the protective layer covering at least a portion of the conductive pad, and exposing one surface of the conductive pad.

14. The substrate of claim 1, further comprising:
a conductive bump on the conductive pad.

15. A semiconductor package comprising:
a substrate; and
a plurality of semiconductor chips side by side on the substrate,
wherein the substrate includes
a base substrate having a front surface, a back surface opposite to the front surface, and a first penetration portion penetrating between the front surface and the back surface,
a wiring structure on the front surface of the base substrate,
an insulation layer on the back surface of the base substrate and having a second penetration portion extending from the first penetration portion,
a penetration via filing a portion of the second penetration portion and filling the first penetration portion such that the penetration via is connected to the wiring structure, and
a conductive pad extending onto a first surface of the insulation layer and filling a remaining part of the second penetration portion such that the conductive pad is connected to the penetration via, and
a surface of the penetration via facing the conductive pad is recessed by 700 nanometers (nm) to 1100 nm from the first surface of the insulation layer.

16. The semiconductor package of claim 15, wherein the substrate electrically connects the semiconductor chips.

17. A substrate manufacturing method comprising:
forming a penetration via in a base substrate such that the penetration via is extended in a direction from a front surface of the base substrate toward a first back surface of the base substrate and such that the penetration via is embedded in the base substrate;
removing the first back surface of the base substrate such that a second back surface is formed and such that the penetration via protrudes from the second back surface of the base substrate;
forming an insulation layer on the second back surface of the base substrate and on a region of the penetration via protruding from the second back surface of the base substrate;
exposing the penetration via by removing a portion of the insulation layer and a portion of the penetration via;
removing a second portion of the penetration via such that the penetration via is recessed by 700 nanometers (nm) to 1100 nm from a first surface of the insulation layer; and
forming a conductive pad on the penetration via such that the conductive pad extends onto the first surface of the insulation layer.

18. The substrate manufacturing method of claim 17, wherein the removing the second portion of the penetration via includes dry etching.

19. The substrate manufacturing method of claim 17, wherein the forming the conductive pad includes
forming a first metal layer extending along a surface of the insulation layer and a surface of the penetration via,
forming a photoresist layer on the first metal layer,
exposing and developing the photoresist layer to form an open region,
filling a second metal layer in the open region of the photoresist layer,
removing the photoresist layer, and
removing a region of the first metal layer that is not covered by the second metal layer.

20. The substrate manufacturing method of claim 17, wherein the forming the insulation layer includes
forming a first insulation layer,
forming a second insulation layer on the first insulation layer, and
forming a third insulation layer on the second insulation layer, and
wherein the third insulation layer is fully removed in the exposing the penetration via.
